(19) United States
(12) Patent Application Publication
(10) Pub. No.: US 2005/0072903 A1
(43) Pub. Date: Apr. 7, 2005

(54) Method and apparatus for selective illumination in a scanner

(76) Inventors: James S. Voss, Fort Collins, CO (US); William Robert Haas, Fort Collins, CO (US); Kirk Steven Tecu, Greeley, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/678,488

(22) Filed: Oct. 2, 2003

(51) Int. Cl. H01L 27/00

(52) U.S. Cl. 250/208.1

(57) ABSTRACT

A scanner that illuminates a partial width of a scan line is disclosed. The scanner first determines the needed scan width and then performs a scan where the full width of the scan is not illuminated.

### FIELD OF THE INVENTION

The field of this invention relates to scanners.

### BACKGROUND OF THE INVENTION

Electronic document scanners and facsimile machines transform an optical image of a document into an electric signal suitable for storing, displaying, printing or electronic transmission. These devices typically use illumination and optical systems to illuminate the object and focus a small area of the illuminated object, usually referred to as the “scan line”, onto a photo sensor array. Along the length of the scan line is typically called the scan width or X-direction. The entire object is then scanned by sweeping the illuminated scan line across the entire object, either by moving the object with respect to the illumination and optical assemblies, or by moving the illumination and optical assemblies relative to the object. This is typically called the scan length or Y-direction.

Images that scanners scan range in size from small objects or photos up to scans of full pages. Typically scanners allow the size of the scanned area or window to be adjusted to match the size of the object to be scanned. A typical scanner allows the window to be adjusted in the x and y directions from one pixel in length up to the full size of the scanning bed. Many scanners allow the user to select or adjust the scan area by doing a low-resolution scan and displaying the results on a computer monitor. The user can then use the mouse to select the scan area for the final scan. Once the final scan area has been selected, a final high-resolution scan is done and saved in computer memory or on the hard disk. The low-resolution scan may be referred to as a preview scan. Other scanners may detect the size of the object to be scanned when the object is loaded using an automatic document feeder (ADF). These scanners typically only perform one scan, using the detected size as the scan window.

The illumination system in most scanners contains a lamp. The type of lamp for many scanners is a fluorescent bulb. Some scanners use an array of light elements, typically light emitting diodes (LED), for illumination.

Some scanners have white strips running along the scan bed underneath the scanner lid. The photo sensor, typically a CCD, is designed such that it can scan the white strip during the scan. A control system uses this white strip to measure the reflected intensity of the lamp during the scan. The scanner may also have a white strip along the top of the scanner underneath the lid. This white strip may be used to help calibrate the CCD and measure the intensity profile of the lamp along the length of the lamp.

Some scanners are now operating from the power supplied by the I/O channel, for example the USB bus. These I/O channels typically supply a limited amount of power. When the width of a scan is known, and is less than the full scan line, scanning while illuminating the full scan line is a waste of power.

Therefore there is a need for a scanner that can illuminate only a portion of the scan line during a scan.

### SUMMARY OF THE INVENTION

A scanner that illuminates a partial width of a scan line is disclosed. The scanner first determines the needed scan width and then performs a scan where the full width of the scan is not illuminated.

Other aspects and advantages of the present invention will become apparent from the following detailed description, taken in conjunction with the accompanying drawings, illustrating by way of example the principles of the invention.

### BRIEF DESCRIPTION OF THE DRAWINGS

FIG. 1 is a top view of the underside of a scanner lid.

FIG. 2 is composite view of an array of light elements and the underside of a scanner lid in an example embodiment of the present invention.

FIG. 3 is flow chart for scanning using selective illumination in an example embodiment of the present invention.

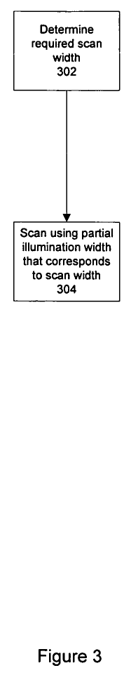

### DETAILED DESCRIPTION OF THE PREFERRED EMBODIMENT

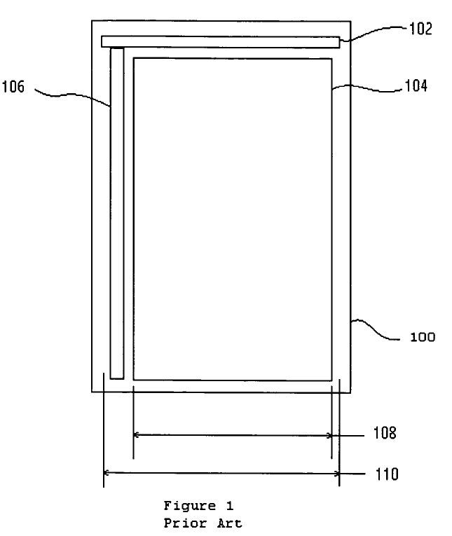

FIG. 1 shows a top view of the underside of a scanner lid (100). The lid has a transparent scan window (104) typically made from glass, a calibration strip (102), and a white strip (106). The calibration strip (102) is used to calibrate the photo sensor, typically a CCD, before a scan begins. Some scanners use a white strip (106) to control the power of the illumination system during a scan (other scanners don't have a white strip). Distance 108 is the maximum scan width available to a user. The CCD and illumination system are typically wider than distance 108. The CCD and illumination system are typically as wide as distance 110. This allows the white strip to be monitored during a scan and allows for tolerance stacking for the location of the CCD with respect to the scan window (104). In today's scanners, the illumination system typically illuminates the full scan width (110) during every scan.

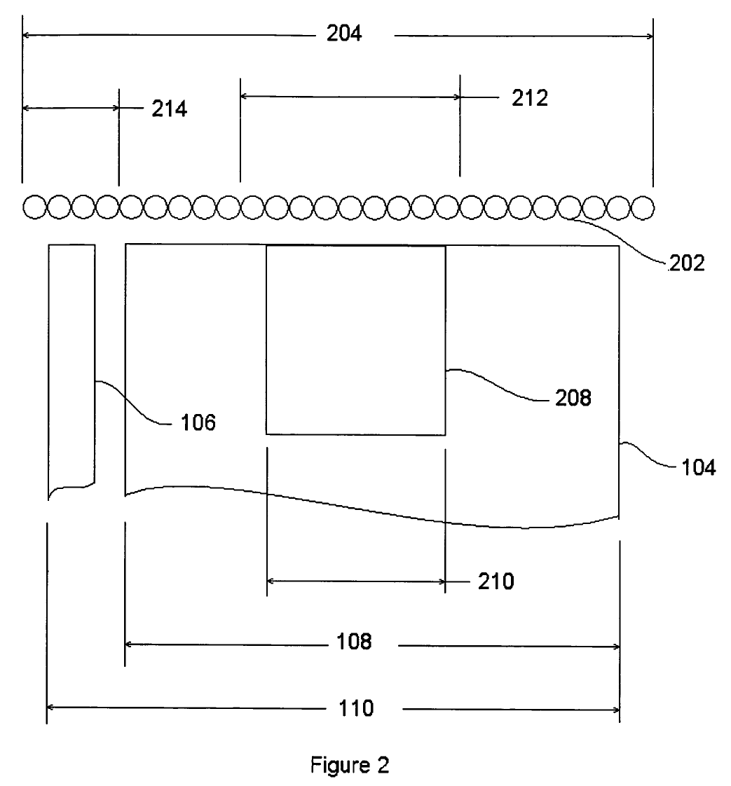

In an example embodiment of the current invention, the illumination system for the scanner would comprise an array of light elements. In a preferred embodiment the light elements would be LED's. Other types of light elements may be used, for example semiconductor LASERS. The scanner would be able to energize all the light elements for one type of scan. The scanner would be able to energize only a segment of the light elements for a different type of scan. FIG. 2 shows an array of light elements (202) in a position for starting a scan (the size and number of individual light elements have been simplified for illustration purposes). The light elements have a maximum length (204) corresponding to the maximum scan width (110). In one type of scan, for example a preview scan, all the light elements would be used (i.e. energized) during the scan. In another type of scan, less than all of the light elements would be used. For example, when a photograph (208) is placed in the middle of the scan window, the scanner would only energize the segment of light elements (212) in the middle of the light elements (202). Notice that the middle light segment (212) may be wider than the actual scan width (210) used for the photograph. This is because the light elements beyond the edge of the actual scan width may be required to properly illuminate the full width of the scan window.

The scanner may also energize a second segment of light elements (214) under the white strip, during the scan. When two small objects need to be scanned, two segments of the light array may be energized (not shown). In many cases the user places the object to be scanned in one corner of the scan window. In these cases, the segment of energized light used for the scan would be at one edge of the scan window (not shown).

In one example embodiment of the current invention, the LED arrays can be controlled down to the individual light element. For example, the energized light segment could start on any individual light element. In another example embodiment of the current invention, the light elements would be grouped into banks, and the light segments used for a scan would only be able to start at the beginning of one of the banks of light elements.

In one example embodiment of the current invention, the width of the scan may be determined (302) using a preview scan. Typically a preview scan is a lower resolution scan of the scan window (104). Once a preview scan is completed, the size of the object to be scanned can be determined. In some scanners the user selects the size to be scanned by dragging the mouse across an image of the preview scan. In other scanners the scanner software automatically determines the size of the object to be scanned using the data from the preview scan. Once the object width has been determined, a second scan can be completed, using only a segment of the full illumination width that corresponds to the object width (304).

In one example embodiment of the current invention, the width of the scan may be determined (302) using additional sensors located in the scanner. For example, the sensors may be placed on the scanner lid, such that when the lid is closed, the sensors detect the size of the object to be scanned. In another example embodiment of the current invention, sensors located in an automatic document or automatic photo-feeder, would detect the size or width of the object to be scanned. Once the object width has been determined, a scan can be completed, using only a segment of the full illumination width that corresponds to the object width (304).

In the preferred embodiment of the current invention the individual light elements are white LEDs. In another example embodiment of the current invention, the array of light elements may contain different color LED grouped together to produce the proper illumination at the scan line, for example red, green and blue LEDs.

LED's typically come in different grades. Higher grades typically last longer than lower grades. In one example embodiment of the current invention, higher grade LED's would be used in areas of the light array that correspond to areas that typically contain an object to be scanned. Two areas in the scan window typically have an object to be scanned more frequently than other areas. The first area is the area that corresponds to the reference corner of the scan window. This area is typically used to reference the object to be scanned. In some scanners the reference corner is the top left corner of the scan window. The second area used more frequently is the middle of the scan window. Automatic photo-feeders typically place the photo to be scanned in the middle of the scan window. By placing the higher grade LEDs in the higher use area, and only using the LED's needed to illuminate the object to be scanned, lower grade LED's may be used in the other areas of the light array. Lower grade LED's typically cost less than higher grade LED's.

The foregoing description of the present invention has been presented for purposes of illustration and description. It is not intended to be exhaustive or to limit the invention to the precise form disclosed, and other modifications and variations may be possible in light of the above teachings. This invention is not limited to marking object to help focus a digital device, this invention can be used to mark other useful objects, for example but not limited to, light sources, areas of interest, and flash points. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

1. A method comprising:
illuminating a full width of a scan line and performing a first scan;
illuminating a partial section of the scan line and performing a second scan.

2. The method of claim 1 where the first scan is done at a lower resolution and the second scan is done at a higher resolution.

3. The method of claim 1 where the scan line has a middle, and where the partial section illuminated during the second scan is in the middle of the scan line.

4. The method of claim 1 where the scan line has an end, and where the partial section illuminated during the second scan is at the end of the scan line.

5. The method of claim 1 where a second partial section of the scan line is illuminated during the second scan.

6. A method comprising:
determining a required scan width, where the required scan width is less than a maximum scan width;
performing a scan where at least the required scan width, but less than the maximum scan width, is illuminated.

7. The method of claim 6 where the required scan width is determined by a sensor other than the sensor used to perform the scan.

8. The method of claim 6 where the required scan width is determined by a sensor located in an automatic document feeder.

9. The method of claim 6 where the required scan width is in a middle of the maximum scan width.

10. The method of claim 6 where the required scan width is at one end of the maximum scan width.

11. A scanner, comprising:
an image sensor configured to sense light from a scan line, the scan line having a width, two ends and a middle;
a plurality of light elements, configured to illuminate the width of the scan line, the plurality of light elements having a maximum length;
control circuitry configured to energize a segment of the light elements during a scan, where the energized segment is less than the maximum length of the plurality of light elements.

12. The scanner of claim 11 where the control circuitry can end the energized segment of light on any light element.

13. The scanner of claim 11 where the control circuitry can start the energized segment of light on any light element.

14. The scanner of claim 11 where the light elements are LED's.

15. The scanner of claim 14 where the LED's are of at least 2 different grades, the first grade being a higher grade and the second grade being a lower grade.

16. The scanner of claim 15 where the lower grade LED's are at one end of the plurality of light elements.

17. The scanner of claim 15 where the higher grade LED's are in a middle of the plurality of light elements.

18. The scanner of claim 11 where the segment of energized lights is at one end of the scan line.

19. The scanner of claim 11 where the segment of energized lights is in the middle of the scan line.

20. A scanner, comprising:
a means for determining a required scan width that is less than a maximum scan width;
a means for illuminating only the required scan width during a scan.
